(19) United States
(12) Patent Application Publication
(10) Pub. No.: US 2024/0146308 A1
(43) Pub. Date: May 2, 2024

(54) CALIBRATION DEVICE AND METHOD FOR CALIBRATING FREQUENCY DRIFT AND ELECTRONIC DEVICE USING THE SAME

(71) Applicant: NUVOTON TECHNOLOGY CORPORATION, HSINCHU CITY (TW)

(72) Inventors: PING-WEN LAI, HSINCHU CITY (TW); TU-HSIU WANG, HSINCHU CITY (TW)

(21) Appl. No.: 18/325,748

(22) Filed: May 30, 2023

(30) Foreign Application Priority Data
Oct. 26, 2022 (TW) 111140682

(51) Int. Cl. H03L 1/02; H03B 5/04

(52) U.S. Cl. CPC H03L 1/025; H03B 5/04

(57) ABSTRACT

A calibration device, method and electronic device using the same provided by embodiments of the present disclosure only need to measure frequency values of two temperatures, then calculate frequency drift rates of various configuration combinations, and select the configuration combination with the smallest frequency drift rate to set configuration values of a trimming module. Thus, the test time can be reduced. In one embodiment, a simple heating device can be directly disposed on the chip package structure of the electronic device, so it is not necessary to use an external heating device for heating, and the environmental space required for placing the external heating device can be reduced.

### CROSS-REFERENCE TO RELATED APPLICATION

This application claims the priority from the TW Patent Application No. 111140682, filed on Oct. 26, 2022, and all contents of such TW Patent Application are comprised in the present disclosure.

### BACKGROUND

### 1. Field of the Invention

The present disclosure relates to a calibration device, a method for calibrating frequency drift and an electronic device using the same, in particular to a calibration device, a method and an electronic device using the same that are able to minimize frequency drift rates via measuring frequency values of two temperatures only.

### 2. Description of the Related Art

The frequency of an output signal generated by an electronic device usually varies with temperature. In particular, an output oscillation signal is provided to the back-end circuit as a reference when the electronic device is an oscillator device. Thus, the back-end circuit can perform corresponding operations at an accurate time point. When the frequency drift rates of the output oscillation signal are too large, the back-end circuit will easily operate at the wrong time point.

At present, it is common to perform the frequency drift compensation to electronic devices that need to produce accurate output signals in the industry. However, an additional circuit is required for the frequency drift compensation. Moreover, the frequency drift compensation circuit also needs to continuously detect the output signal when the electronic device is in operation. Therefore, in addition to the requirement of additional circuit area, additional power consumption will be generated. It does not match the current trend of electronic products being thin, light, small, energy saving and carbon saving.

Another manner is to carry out corresponding trimming to calibrate the frequency drift of the electronic device before delivery. Once it is determined how the electronic device should be trimmed, the corresponding trimming parameters are directly stored, for example, they are stored in a non-volatile memory, and the electronic device uses the trimming parameters to work after delivery. However, in the related art, it is necessary to test the frequency values of more than two temperatures and perform calculation and adjustment to determine which trimming parameter is more accurate. Therefore, the test time is long and it is time-consuming. On the other hand, in the related art, the electronic device is heated by an external heating device, but the heating device is relatively expensive and may occupy more space.

### SUMMARY

Embodiments of the present disclosure provide a calibration device. The calibration device is used to calibrate a frequency drift of an electronic device. The calibration device comprises a trimming module and a configuration selection module. The trimming module is electrically connected to an output signal generating circuit. The trimming module comprises a proportional to absolute temperature (PTAT) trimming device, a complementary to absolute temperature (CTAT) trimming device and a reference trimming device to trim a frequency of an output signal of the output signal generating circuit. The PTAT trimming device is defined with a plurality of first configuration values, and the CTAT trimming device is defined with a plurality of second configuration values. One of the first configuration values and one of the second configuration values form one of a plurality of first configuration combinations. The configuration selection module is electrically connected to the trimming module. When the temperature of the electronic device is the first temperature, the configuration selection module respectively sets the PTAT trimming device and the CTAT trimming device based on the first configuration combinations to obtain a plurality of first frequency values of the output signal corresponding to the first configuration combinations. For the first configuration combinations, the configuration selection module respectively selects a plurality of third configuration values of the reference trimming device which make the frequency of the output signal close to a target value and a plurality of second frequency values of the frequency of the output signal corresponding to the selected third configuration values. Then, the configuration selection module records the first configuration combinations and the corresponding third configuration values into a plurality of second configuration combinations. When the temperature of the electronic device is a second temperature greater than the first temperature, the configuration selection module obtains a plurality of third frequency values of the output signal of the second configuration combinations. Then, the configuration selection module calculates a plurality of frequency drift rates of the second configuration combinations based on the second frequency values and the third frequency values, and selects the second configuration combination with the smallest frequency drift rate The configuration selection module sets a plurality of configurations of the PTAT trimming device, CTAT trimming device and the reference trimming device based on the selected second configuration combination.

The embodiments of the present disclosure also provide another calibration device. The calibration device is used to calibrate a frequency drift of an electronic device. The calibration device comprises a trimming module and a configuration selection module. The trimming module is electrically connected to an output signal generating circuit of the electronic device. The trimming module comprises a proportional to absolute temperature (PTAT) trimming device and a complementary to absolute temperature (CTAT) trimming device to trim a frequency of an output signal of the output signal generating circuit. The PTAT trimming device is defined with a plurality of first configuration values, and the CTAT trimming device is defined with a plurality of second configuration values. Also, one of the first configuration values and one of the second configuration values form one of a plurality of configuration combinations. The configuration selection module is electrically connected to the trimming module. When the temperature of the electronic device is the first temperature, the configuration selection module respectively sets the PTAT trimming device and the CTAT trimming module based on the configuration combinations to respectively obtain a plurality of first frequency values of the output signal corresponding to the configuration combinations. When the temperature of the electronic device is a second temperature greater than the first temperature, the configuration selection module obtains a plurality of second frequency values of the output signal of the configuration combinations. Then, the configuration selection module calculates a plurality of frequency drift rates of the configuration combinations based on the second frequency values and the first frequency value. The configuration selection module selects the configuration combination with the smallest frequency drift rate to set a plurality of configurations of the PTAT trimming device and the CTAT trimming device.

The embodiments of the present disclosure also provide an electronic device. The electronic device comprises the aforementioned calibration device and the output signal generating circuit.

The embodiments of the present disclosure provide another electronic device. The electronic device comprises the aforementioned calibration device and the output signal generating circuit. The calibration device further comprises a heating device. The heating device is used to increase the temperature of the electronic device from the first temperature to the second temperature. The configuration selection module, the trimming module and the output signal generating circuit are packaged in a chip package structure. The heating device is disposed on a chip package structure, and the heating device is electrically connected to a plurality of pins of the chip package structure.

The embodiments of the present disclosure also provide a calibration method. The calibration method comprises the following steps. A trimming module is provided. The trimming module is electrically connected to an output signal generating circuit of the electronic device. The trimming module comprises a proportional to absolute temperature (PTAT) trimming device, a complementary to absolute temperature (CTAT) trimming device and a reference trimming device to trim a frequency of an output signal of the output signal generating circuit. The PTAT trimming device is defined with a plurality of first configuration values, and the CTAT trimming is defined with a plurality of second configuration values. One of the first configuration values and one of the second configuration values form one of a plurality of configuration combinations. When the temperature of the electronic device is the first temperature, the PTAT trimming device and the CTAT trimming device is set respectively based on each of the first configuration combinations to respectively obtain a plurality of first frequency values of the output signal corresponding to the first configuration combinations. Then, for the first configuration combinations, a plurality of third configuration values of the reference trimming device which make the frequency of the output signal close to a target frequency value and a plurality of second frequency values of the frequency of the output signal corresponding to the third configuration values are respectively selected. As well, the first configuration combinations and the corresponding third configuration values are recorded into a plurality of second configuration combinations. When the temperature of the electronic device is the second temperature greater than the first temperature, a plurality of third frequency values of the output signal of the second configuration combinations are obtained. Then, a plurality of frequency drift rates of the second configuration combinations are calculated based on the second frequency values and the third frequency value. As well, the second configuration combination with the smallest frequency drift is selected to set a plurality of configurations of the PTAT trimming device, the CTAT trimming device and the reference trimming device.

To sum up, the calibration device, the method and the electronic device using the same according to the embodiments of the present disclosure can calculate frequency drift rates of various configuration combinations and select the configuration combination with the smallest frequency drift rate to set the configuration values of the trimming module only via measuring the frequency values of two temperatures. Thus, the test time can be reduced. In one of the embodiments, a simple heating device can be directly disposed on the chip package structure of the electronic device. As a result, there is no need to use an external heating device for heating, and the space required for placing heating device can be reduced.

To further understand the technology, means, and effects of the present disclosure, reference may be made by the detailed description and drawing as follows. Accordingly, the purposes, features and concepts of the present disclosure can be thoroughly and concretely understood. However, the following detail description and drawings are only used to reference and illustrate the implementation of the present disclosure, and they are not used to limit the present disclosure.

### BRIEF DESCRIPTION OF THE DRAWINGS

The drawings are provided to make the persons with ordinary knowledge in the field of the art further understand the present disclosure, and are incorporated into and constitute a part of the specification of the present disclosure. The drawings illustrate demonstrated embodiments of the present disclosure, and are used to explain the principal of the present disclosure together with the description of the present disclosure.

FIG. 1 is a block diagram of an electronic device with a calibration device for calibrating a frequency drift according to an embodiment of the present disclosure;

FIG. 2 is a block diagram of an electronic device with a calibration device for calibrating a frequency drift according to another embodiment of the present disclosure;

FIG. 3 is a flowchart of a calibration method for calibrating a frequency drift according to an embodiment of the present disclosure;

FIG. 4 is a schematic diagram of a waveform for testing whether a frequency of an output signal is close to a target frequency value according to an embodiment of the present disclosure;

FIG. 5A is a curve chart of temperature and frequency of an output signal for a CTAT trimming device under different configuration values according to an embodiment of the present disclosure;

FIG. 5B is a curve chart of temperature and frequency of an output signal for a PTAT trimming device under different configuration values according to an embodiment of the present disclosure;

FIG. 6 is a schematic diagram of how to select a configuration of a CTAT trimming device and a configuration of a PTAT trimming device according to an embodiment of the present disclosure; and

FIG. 7 is a schematic diagram of an electronic device with a heating device packaged in a chip package structure according to an embodiment of the present disclosure.

### DESCRIPTION OF THE PREFERRED EMBODIMENTS

The embodiments of the present disclosure are described in detail as reference, and the drawings of the present disclosure are illustrated. In the case of possibility, the element symbols are used in the drawings to refer to the same or similar components. In addition, the embodiment is only one approach of the implementation of the design concept of the present disclosure, and the following multiple embodiments are not intended to limit the present disclosure.

A calibration device, a method and an electronic device using the same of embodiments of the present disclosure obtain two frequency values of an output signal of the electronic device at two different temperatures for each of several configuration combinations formed by several configuration values of a complementary to absolute temperature (CTAT) trimming device and several configuration values of a proportional to absolute temperature (PTAT) trimming device. Also, frequency drift rates are calculated accordingly. Next, the configuration combination with the smallest frequency drift is selected to set the configuration values of the CTAT trimming device and the PTAT trimming device. Since only two frequency values at the two different temperatures need to be measured, it is not necessary to measure frequency values corresponding to more than two temperatures as the related art. Therefore, the embodiments of the present disclosure can reduce the test time. Furthermore, in one of the embodiments of the present disclosure, a heating device is implemented via heating wires, and the heating wires are disposed on a chip package structure of the electronic device. Thus, there is no need to use an additional external heater with a large volume.

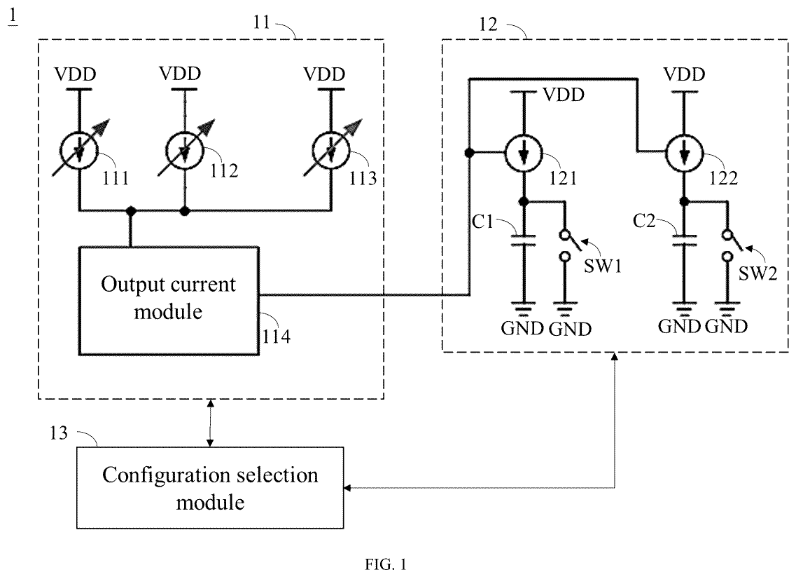

Firstly, please refer to FIG. 1, FIG. 1 is a block diagram of an electronic device with a calibration device for calibrating a frequency drift according to an embodiment of the present disclosure. An electronic device 1 comprises a calibration device which comprises a trimming module 11 and a configuration selection module 13, and an output signal generating circuit 12. The calibration device is used to calibrate the frequency drift of an output signal of the electronic device 1. The trimming module 11 is electrically connected to the output signal generating circuit 12 of the electronic device 1. The configuration selection module 13 is electrically connected to the trimming module 11.

The trimming module 11 comprises a proportional to absolute temperature (PTAT) trimming device 111, a complementary to absolute temperature (CTAT) trimming device 112 and a reference trimming device 113, and is configured to trim the frequency of the output signal of the output signal generating circuit 12. In this embodiment, the trimming module 11 uses a current trimming module. That is, the frequency value of the output signal is changed via trimming the current, so that the frequency drift of the output signal is compensated. The PTAT trimming device 111 is a PTAT trimming current generator, the CTAT trimming device 112 is a CTAT trimming current generator, and the reference trimming 113 is a reference trimming current generator. The PTAT trimming device 111 is defined with a plurality of configuration values, and the CTAT trimming device 112 is defined with a plurality of configuration values. One of the configuration values of the PTAT trimming device 111 and one of the configuration values of the CTAT trimming deice 112 form one of a plurality of configuration combinations.

Additionally, the trimming module 11 further comprises an output current module 114. The PTAT trimming current generator, the CTAT trimming current generator and the reference trimming current generator are connected in parallel. That is, one end of the PTAT trimming current generator, one end of the CTAT trimming current generator and one end of the reference trimming current generator are respectively connected to the system voltage VDD. The other end of the PTAT trimming current generator, the other end of the CTAT trimming current generator and the other end of the reference trimming current generator are connected to the output current module 114. The output current module 114 is used to receive several currents generated by the PTAT trimming current generator, the CTAT trimming current generator and the reference trimming current generator. Then, the output current module 114 adds up the received currents and generates a sum current to control the frequency of the output signal of the output signal generating circuit 12.

The configuration selection module 13 may be implemented via a pure hardware circuit. For example, a hardware circuit is implemented via a Field Programmable Gate Array (FPGA) or an Application Specific Integrated Circuit (ASIC), or the configuration selection module 13 may implemented via a microcontroller executing specific firmware. When the temperature of the electronic device 1 is the first temperature, for example, 25 degrees Celsius, the configuration selection module 13 respectively sets the PTAT trimming device 111 and the CTAT trimming device 112 based on each of the configuration combinations to respectively obtain several first frequency values corresponding to the output signal for the configuration combinations. For example, both of the PTAT trimming device 111 and the CTAT trimming device 112 use two bits to represent the configuration values, there are 16 configuration combinations in total. For each configuration combination, when the temperature of the electronic device 1 is the first temperature, the configuration selection module 13 obtains the frequency value of the output signal of the electronic device 1.

The frequency value of the output signal may be quite different from the target frequency value expected by users before the configuration values of the reference trimming device 113 are specifically adjusted. For the aforementioned configuration combinations, the configuration selection module 13 respectively selects the configuration values of the reference trimming device 113 which make the frequency of the output signal close to the target frequency value and the frequency values of the frequency of the output signal corresponding to the configuration values of the reference trimming device 113. It is noted that the aforementioned “close to the target frequency value” means that the difference of the target frequency value and the frequency value of the output signal is less than ±2.5%, but the present disclosure is not limited thereto. The configuration selection module 13 records the original plurality of configuration combinations and the corresponding configuration values of the reference trimming device 113 into a plurality of specific configuration combinations. For example, when the configuration value of the PTAT trimming device 111 is 10 and the configuration value of the CTAT trimming device 112 is 11, the frequency value of the output signal is 10 MHz. but the target frequency value is 16 MHz. When the configuration value of the reference trimming device 113 is 00, the frequency value of the output signal can be made as 16 MHz. Therefore, the recorded information of the specific configuration combinations comprises the configuration values of the PTAT trimming device 111 being 10, the configuration values of the CTAT device 112 being 11 and the configuration values of the reference trimming device 113 being 00.

Next, a heating device is used to raise the temperature of the electronic device 1 from the first temperature to the second temperature, for example, 125 degrees Celsius. It is noted that the heating device may be a part of the calibration device or an external heater. When the temperature of the electronic device 1 is the second temperature, the configuration selection module 13 obtains several frequency values of the output signal of the specific configuration combinations. Then, the configuration selection module 13 calculates several frequency drift rates of the specific configuration combinations based on the frequency values at the first temperature, that is, the frequency values close to the target frequency value and the frequency values at the second temperature. The configuration selection module 13 selects the specific configuration combination with the smallest frequency drift rate to set the several configurations of the PTAT trimming device 111, the CTAT trimming 112 and the reference trimming device 113 based on the selected specific configuration combination. For example, assume that there are 16 specific configuration combinations. When the configuration value of the PTAT trimming device 111 is 10, the configuration value of the CTAT trimming device 112 is 11 and the configuration value of the reference trimming device 113 is 00, the frequency drift rate of the specific configuration combinations is the smallest. The configuration combination is selected so that the configuration value of the PTAT trimming device 111 is 10, the configuration value of the CTAT trimming device 112 is 11, and the configuration value of the reference trimming device 113 is 00. In this way, the frequency drift rates can be minimized. Unlike the related art, the embodiments of the present disclosure only need to measure the frequency values of two temperatures.

Moreover, in one of the embodiments of the present disclosure, the output signal generating circuit 12 may be an oscillator circuit. The oscillator circuit comprises current generators 121, 122, switches SW1, SW2, capacitors C1 and C2. The power end of the current generator 121 is electrically connected to the system voltage VDD, and the power end of the current generator 122 is electrically connected to the system voltage VDD. The control end of the current generator 121 is electrically connected to the output current module 114 of the trimming module 11, and the control end of the current generator 122 is electrically connected to the output current module 114 of the trimming module 11. The control ends of the current generators 121 and 122 are controlled by the output current value output from the trimming module 11. The current output end of the current generator 121 provides a charging current to the capacitor C1 and the current output end of the current generator 122 provides a charging current to the capacitor C2. One end of the switch SW1 is electrically connected to the low voltage, for example, a ground voltage GND. One end of the switch SW2 is electrically connected to the low voltage, for example, the ground voltage GND. The switches SW1 and SW2 are controlled by oscillation control signals. One end of the capacitor C1 is electrically connected to a current output end of the current generator 121 and the other end of the switch SW1, and the other end of the capacitor C1 is electrically connected to the low voltage. When the switch SW1 is open, the capacitor C1 receives the charging current to be charged. When the switch SW1 is turned on, the capacitor C1 is used to discharge. One end of the capacitor C2 is electrically connected to a current output end of the current generator 122 and the other end of the switch SW2, and the other end of the capacitor C2 is electrically connected to the low voltage. When the switch SW2 is open, the capacitor C2 receives the charging current to be charged. When the switch SW2 is turned on, the capacitor C2 is used to discharge.

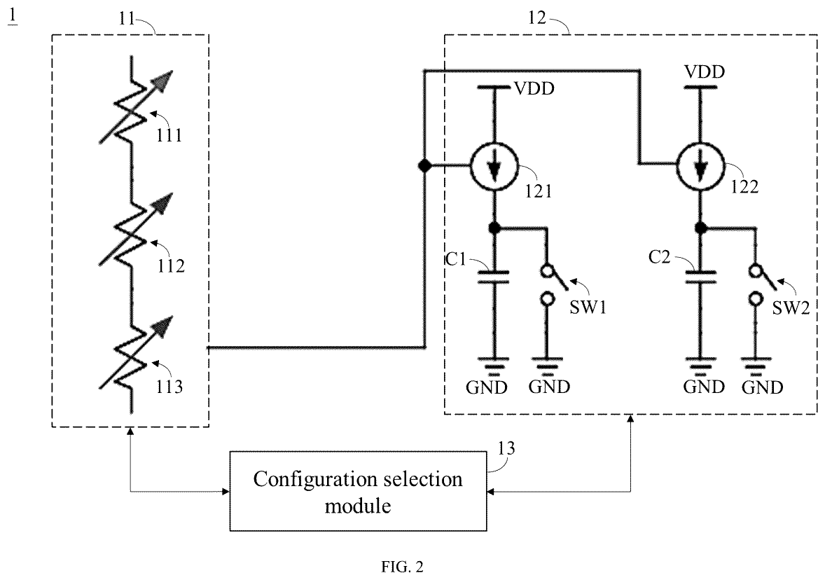

Next, please refer to FIG. 2, FIG. 2 is a block diagram of an electronic device with a calibration device for calibrating a frequency drift according to another embodiment of the present disclosure. The difference between the embodiments in FIG. 2 and the embodiments in FIG. 1 is that the trimming module 11 uses a resistance trimming module instead. Thus, the PTAT trimming device 111 is a PTAT trimming resistor, the CTAT trimming device 112 is a CTAT trimming resistor and the reference trimming device 113 is a reference trimming resistor. Besides, the PTAT trimming resistor, the CTAT trimming resistor and the reference trimming resistor are connected in series.

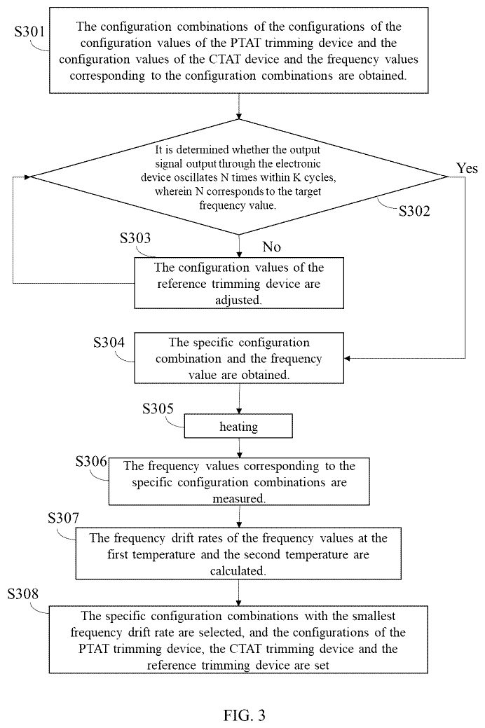

Further, please refer to FIG. 3, FIG. 3 is a flowchart of a calibration method for calibrating a frequency drift according to an embodiment of the present disclosure. Firstly, in step S301, the configuration combinations are formed by obtaining the configuration values of the PTAT trimming device and the configuration values of the CTAT trimming device. For the configuration combinations, the frequency values of the frequency of the output signal for the electronic device are obtained.

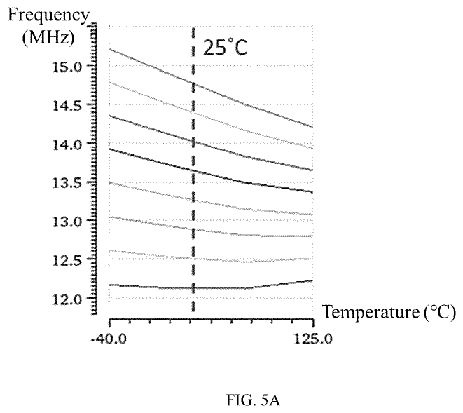

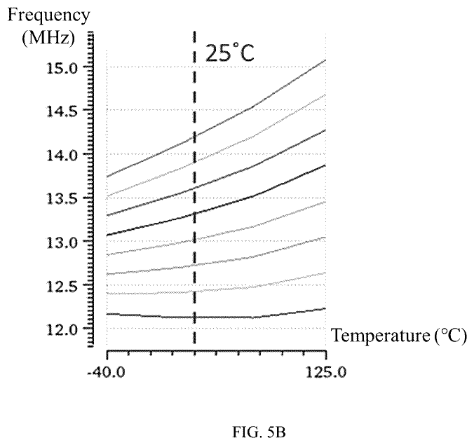

Please refer to FIG. 5A and FIG. 5B together, FIG. 5A is a curve chart of temperature and frequency of an output signal for a CTAT trimming device under different configuration values according to an embodiment of the present disclosure, and FIG. 5B is a curve chart of temperature and frequency for an output signal of a PTAT trimming device under different configuration values according to an embodiment of the present disclosure. As shown in FIG. 5A, for various configuration values of the configurations of the CTAT trimming device, there are corresponding curves to represent the relationship between the temperature and the frequency of the output signal. As shown in FIG. 5B, for various configuration values of the configurations of the PTAT trimming device, there are corresponding curves to represent the relationship between the temperature and the frequency of the output signal. Therefore, in step S301, the configuration combinations are obtained firstly. Then, for the configuration combinations, the frequency values of the frequency of the output signal for the electronic device are obtained.

Please continue to refer to FIG. 3, the frequency values of the frequency of the output signal for the electronic device corresponding to the configuration combinations may not be close to the target frequency value. Therefore, it is still necessary to select the configuration values of the corresponding reference trimming module for each configuration combination, so that the frequency value of the frequency of the output signal for the electronic device corresponding to the configuration combinations is close to or equal to the target frequency value. In step S302, it is determined whether the output signal output by the electronic device oscillates N times within K periods, wherein N is corresponding to the target frequency value. When the output signal output by the electronic device oscillates N times within K periods, step S304 is proceeded. Otherwise, step S303 is proceeded. In step S303, the configuration values of the reference trimming device are adjusted, and then the step S302 is proceeded. In step S304, the aforementioned specific configuration combinations and the frequency values close to the target frequency value are obtained, that is, the configuration value of the reference trimming module is adjusted to make the frequency of the output signal close to the frequency value of the target frequency value based on the first temperature. That is, each specific configuration combination comprises three configuration values of the PTAT trimming device, the CTAT trimming device and the reference trimming device, and then step S305 is proceeded.

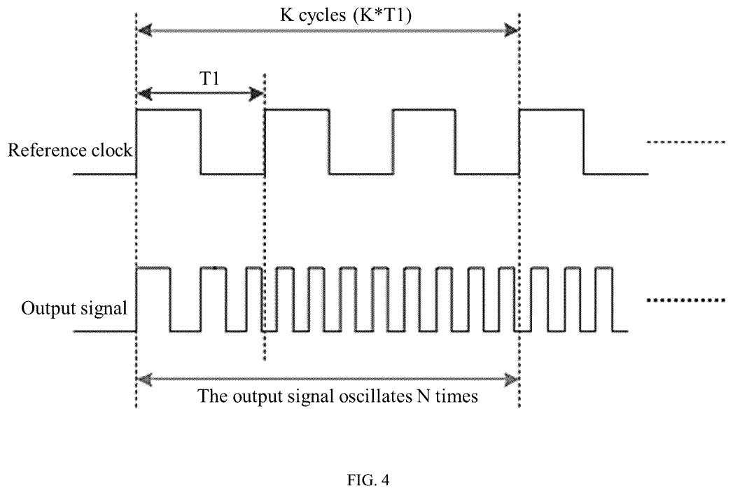

Please refer to FIG. 4, FIG. 4 is a schematic diagram of a waveform for testing whether a frequency of an output signal is close to a target frequency value according to an embodiment of the present disclosure. In FIG. 4, an ideal clock signal is input, and the period of the clock signal is obtained as a reference time. Then, for each configuration combination, the configuration selection module tests whether the output signal oscillates a specific number of times, for example, N times within a specific time. The length of the specific time is a specific number of reference clock periods, for example, K reference clock periods. When the output signal oscillates the specific number of times within the specific time, for the present configuration combination, the configuration selection module determines that the configuration value of the reference trimming device makes the frequency of the output signal close to the target frequency value. The three configuration values of the PTAT trimming device, the CTAT trimming device and the reference trimming device are recorded into the specific configuration combinations. When the output signal does not oscillate the specific number of times within the specific time, for the present configuration combination, the configuration selection module determines that the configuration value of the reference trimming device does not make the frequency of the output signal close to the target frequency value. Therefore, it is necessary to adjust the configuration value of the reference trimming device. Next, the test is repeated until the configuration value of the reference trimming device makes the frequency of the output signal close to the target frequency value.

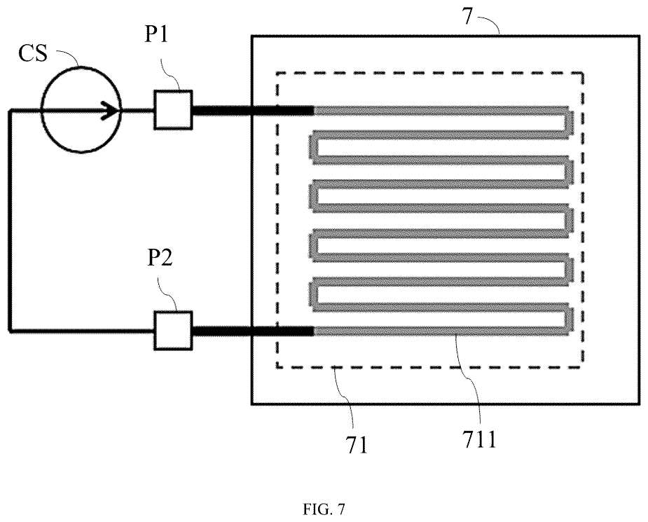

Please continue to refer to FIG. 3, after the specific configuration combinations are obtained, in step S305, the electronic device is heated to raise the temperature from the first temperature to the second temperature. Please refer to FIG. 7 and FIG. 3 at the same time, FIG. 7 is a schematic diagram of an electronic device with a heating device packaged in a chip package structure according to an embodiment of the present disclosure. In one of the embodiments of the present disclosure, the calibration device of the electronic device 7 may further comprises a heating device 71. The heating device 71 is implemented via a sinuous heating wire 711. In this embodiment, the trimming module, the configuration selection module and the output signal generating circuit may be packaged in a chip package structure. Besides, the heating wire 711 is disposed on the chip package structure. Two ends of the heating wire 711 may be connected to two pins P1 and P2 of the chip package structure, and two ends of the current source CS may be electrically connected to the two pins P1 and P2 of the chip package structure. Therefore, whether the electronic device 7 is heated is controlled by the current of the current source CS.

Next, please continue to refer to FIG. 3. In step S306, the configuration selection module measures the plurality of frequency values corresponding to the specific configuration combinations. In step S307, the configuration selection module calculates the frequency drift rates of the specific configuration combinations based on the frequency values at the second temperature and the frequency values at the first temperature of the specific configuration combinations. At the first temperature, the configuration values of the reference trimming module are adjusted to make the frequency of the output signal close to the frequency value of the target frequency value. Finally, in step S308, the configuration selection module selects the specific configuration combination with the smallest frequency drift rate. Also, the configurations of the PTAT trimming device, the CTAT trimming device and the reference trimming device are set based on the selected specific configuration combination. In this way, when the output signal output by the electronic device operates in the frequency range close to the target frequency value, it has the smallest frequency drift.

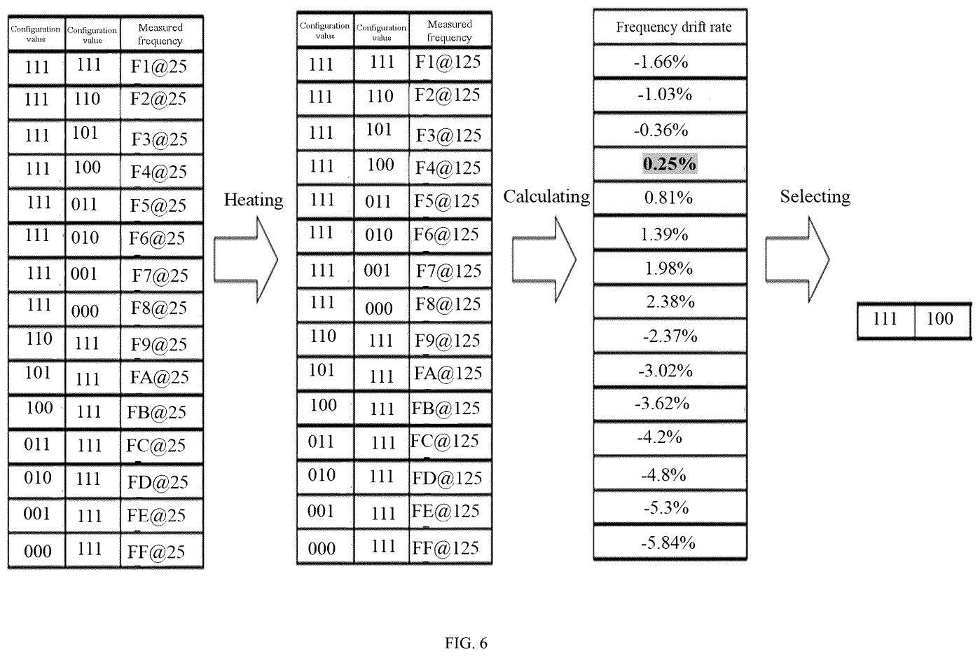

Please refer to FIG. 6, FIG. 6 is a schematic diagram of how to select a configuration of a CTAT trimming device and a configuration of a PTAT trimming device according to an embodiment of the present disclosure. At the first temperature, for example 25 degrees Celsius, as shown in the leftmost table of FIG. 6, there are 15 configuration combinations of the configuration values of the CTAT trimming device and the configuration values of the PTAT trimming device in total. Also, the configuration values of the reference trimming device, not shown in FIG. 6, are adjusted, so that the frequency values of the frequency of the output signal output via the 15 configuration combinations in the leftmost table of FIG. 6 are close to the target frequency values. For the 15 configuration combinations, the configuration values of the CTAT trimming device and the PTAT trimming device and the selected configuration values of the reference trimming module which make the frequency of the output signal close to the configuration value of the target frequency value are recorded into the specific configuration combinations. In FIG. 6, the 15 specific configuration combinations and the frequency values F1 @25˜FF@25, that is, the frequency value close to the target frequency value of the frequency values of the output signal for the 15 specific configuration combinations at the first temperature are also recorded.

Next, the electronic device is heated to make the temperature of the electronic device raise from the first temperature to the second temperature. For example, the second temperature is raised to 125 degrees Celsius. Then, the frequency values F1@25˜FF@25 of the output signal for the 15 specific configuration combinations at the second temperature are recorded. Then, the frequency drift rates of the 15 specific configuration combinations are calculated. For example, the frequency drift value of the first specific configuration combination is (F1 @125−F1 @25)/F1 @25=−1.66%. Further, the specific configuration combination with the lowest frequency drift rate is selected to set the configuration values of the CTAT trimming device, the PTAT trimming device and the reference trimming module, respectively. In this embodiment, when the configuration value of the CTAT trimming device is 111 and the configuration value of the PTAT trimming device is 100, the frequency drift rate is smallest. It is noted that the configuration values of the reference trimming device are not shown in FIG. 6. As well, the configuration values of the reference trimming device are set to make the frequency value of the output signal close to the configuration value of the target frequency value.

By the way, in another embodiment of the present disclosure, the trimming module may not comprise the reference trimming device. Therefore, the embodiments of the present disclosure also provide another calibration device. The calibration device is used to calibrate the frequency drift of the electronic. The calibration device comprises the trimming module and the configuration selection module. The trimming module is electrically connected to the output signal generating circuit of the electronic device. The trimming module comprises the proportional to absolute temperature (PTAT) trimming device and the complementary to absolute temperature (CTAT) trimming device to trim the frequency of the output signal of the output signal generating circuit. The PTAT trimming device is defined with the plurality of first configuration values, and the CTAT trimming device is defined with the plurality of second configuration values. As well, one of the first configuration values and one of the second configuration values form one of the plurality of configuration combinations. The configuration selection module is electrically connected to the trimming module. When the temperature of the electronic device is the first temperature, the configuration selection module respectively sets the PTAT trimming device and CTAT trimming device based on each of the configuration combinations, to obtain the frequency values of the output signal corresponding to the configuration combinations, respectively. When the temperature of the electronic device is the second temperature greater than the first temperature, the configuration selection module obtains the frequency values of the output signal of the configuration combinations. Then, the configuration selection module calculates the frequency drift rates of the configuration combinations based on the frequency values at the first temperature and the frequency values at the second temperature to select the configuration combination with the smallest frequency drift rate. The configuration selection module sets the plurality of configurations of the PTAT trimming device and the CTAT trimming device based on the selected configuration combination.

As the stated as above, since the calibration device, the method and the electronic device using the same of the embodiments of the present disclosure only need to measure two frequency values at two different temperatures, it is not necessary to measure frequency values corresponding to more than two temperatures as the related art. Therefore, the test time can be reduced. Furthermore, in one of the embodiments of the present disclosure, the heating device is implemented via the heating wire, and the heating wire is disposed on the chip package structure of the electronic device. As a result, there is no need to use an external heating device for heating, and the space required for calibrating can be reduced.

It should be understood that the examples and the embodiments described herein are for illustrative purpose only, and various modifications or changes in view of them will be suggested to those skilled in the art, and will be comprised in the spirit and scope of the application and the appendix with the scope of the claims.

What is claimed is:

1. A calibration device for calibrating a frequency drift of an electronic device, comprising:
a trimming module, electrically connected to an output signal generating circuit of the electronic device, comprising a proportional to absolute temperature (PTAT) trimming device, a complementary to absolute temperature (CTAT) trimming device, and a reference trimming device, and configured to trim a frequency of an output signal of the output signal generating circuit,
wherein the PTAT trimming device is defined with a plurality of first configuration values, and the CTAT trimming device is defined with a plurality of second configuration values, and
wherein one of the plurality of first configuration values and one of the plurality of second configuration values form one of a plurality of first configuration combinations; and
a configuration selection module, electrically connected to the trimming module,
wherein when a temperature of the electronic device is a first temperature, the configuration selection module respectively sets the PTAT trimming device and the CTAT trimming device based on the first configuration combinations to obtain a plurality of first frequency values of the output signal corresponding to the plurality of first configuration combinations, wherein for the plurality of first configuration combinations, the configuration selection module selects a plurality of third configuration values of the reference trimming device which make the frequency of the output signal close to a target frequency value, and a plurality of second frequency values of the frequency of the output signal corresponding to the plurality of selected third configuration values, and the configuration selection module records the plurality of first configuration combinations and the corresponding plurality of third configuration values into a plurality of second configuration combinations; and
wherein when the temperature of the electronic device is a second temperature greater than the first temperature, the configuration selection module obtains a plurality of third frequency values of the output signal of the plurality of second configuration combinations, then calculates a plurality of frequency drift rates of the plurality of second configuration combinations based on the plurality of third frequency values and the plurality of second frequency values, to select the second configuration combination with a smallest frequency drift rate, and the configuration selection module sets a plurality of configurations of the PTAT trimming device, CTAT trimming device and the reference trimming device based on the selected second configuration combination.

2. The calibration device according to claim 1, wherein the PTAT trimming device is a PTAT trimming resistor, the CTAT trimming device is a CTAT trimming resistor, and the reference trimming device is a reference trimming resistor, and
wherein the PTAT trimming resistor, the CTAT trimming resistor and the reference trimming resistor are connected in series.

3. The calibration device according to claim 1, wherein the PTAT trimming device is a PTAT trimming current generator, the CTAT trimming device is a CTAT trimming current generator, and the reference trimming device is a reference trimming current generator,
wherein the PTAT trimming current generator, the CTAT trimming current generator and the reference trimming current generator are connected in parallel, and
wherein the trimming module further comprises an output current module, configured to receive a plurality of currents generated by the PTAT trimming current generator, the CTAT trimming current generator, and the reference trimming current generator, and generate a sum current which is the sum of the plurality of received currents to the output signal generating circuit.

4. The calibration device according to claim 1, further comprising:
a heating device, configured to increase the temperature of the electronic device from the first temperature to the second temperature.

5. The calibration device according to claim 1, wherein for the first configuration combinations, the configuration selection module tests whether the output signal oscillates a specific number of times within a specific time, and a length of the specific time is a specific plurality of reference clock periods,
wherein when the output signal oscillates the specific number of times within the specific time, for the first configuration combinations, the configuration selection module determines that the third configuration values of the reference trimming device makes the frequency of the output signal close to the target frequency value based on the first configuration combination, and
wherein when the output signal does not oscillate the specific number of times within the specific time, for the first configuration combinations, the configuration selection module determines that the third configuration values of the reference trimming device does not make the frequency of the output signal close to the target frequency value based on the first configuration combination, then the configuration selection module adjusts the third configuration values of the reference trimming device, and repeats testing until the configuration values of the reference trimming device makes the frequency of the output signal close to the target frequency value.

6. A calibration device for calibrating a frequency drift of an electronic device, comprising:
a trimming module, electrically connected to an output signal generating circuit of the electronic device, comprising a proportional to absolute temperature (PTAT) trimming device and a complementary to absolute temperature (CTAT) trimming device, and configured to trim a frequency of an output signal of the output signal generating circuit,
wherein the PTAT trimming device is defined with a plurality of first configuration values, and the CTAT trimming device is defined with a plurality of second configuration values, and
wherein one of the plurality of first configuration values and one of the plurality of second configuration values form one of a plurality of configuration combinations; and
a configuration selection module, electrically connected to the trimming module,
wherein when a temperature of the electronic device is a first temperature, the configuration selection module respectively sets the PTAT trimming device and the CTAT trimming module based on the plurality of configuration combinations to obtain a plurality of first frequency values of the output signal corresponding to the plurality of configuration combinations, and
wherein when the temperature of the electronic device is a second temperature greater than the first temperature, the configuration selection module obtains a plurality of second frequency values of the output signal of the plurality of configuration combinations, calculates a plurality of frequency drift rates of the plurality of configuration combinations based on the plurality of second frequency values and the plurality of first frequency values, and selects the configuration combination with a smallest frequency drift rate to set a plurality of configurations of the PTAT trimming device and the CTAT trimming device.

7. An electronic device, comprising:
a calibration device, configured to calibrate a frequency drift of the electronic device, comprising:
a trimming module, electrically connected to an output signal generating circuit of the electronic device, comprising a proportional to absolute temperature (PTAT) trimming device, a complementary to absolute temperature (CTAT) trimming device and a reference trimming device, and configured to trim a frequency of an output signal of the output signal generating circuit,
wherein the PTAT trimming device is defined with a plurality of first configuration values, and the CTAT trimming device is defined with a plurality of second configuration values, and
wherein one of the plurality of first configuration values and one of the plurality of second configuration values form one of a plurality of first configuration combinations; and
a configuration selection module, electrically connected to the trimming module,
wherein when a temperature of the electronic device is a first temperature, the configuration selection module respectively sets the PTAT trimming device and the CTAT trimming device based on the first configuration combinations to obtain a plurality of first frequency values of the output signal corresponding to the plurality of first configuration combinations, wherein for the plurality of first configuration combinations, the configuration selection module selects a plurality of third configuration values of the reference trimming device which make the frequency of the output signal close to a target frequency value and a plurality of second frequency values of the frequency of the output signal corresponding to the plurality of selected third configuration values, and records the plurality of first configuration combinations and the corresponding plurality of third configuration values into a plurality of second configuration combinations; and
wherein when the temperature of the electronic device is a second temperature greater than the first temperature, the configuration selection module obtains a plurality of third frequency values of the output signal of the plurality of second configuration combinations, then calculates a plurality of frequency drift rates of the plurality of second configuration combinations based on the plurality of third frequency values and the plurality of second frequency values to select the second configuration combination with a smallest frequency drift rate, and the configuration selection module sets a plurality of configurations of the PTAT trimming device, CTAT trimming device and the reference trimming device based on the selected second configuration combination; and
the output signal generating circuit.

8. The electronic device according to claim 7, wherein the PTAT trimming device is a PTAT trimming resistor, the CTAT trimming device is a CTAT trimming resistor, and the reference trimming device is a reference trimming resistor, and
wherein the PTAT trimming resistor, the CTAT trimming resistor and the reference trimming resistor are connected in series.

9. The electronic device according to claim 7, wherein the PTAT trimming device is a PTAT trimming current generator, the CTAT trimming device is a CTAT trimming current generator, and the reference trimming device is a reference trimming current generator,
wherein the PTAT trimming current generator, the CTAT trimming current generator and the reference trimming current generator are connected in parallel, and
wherein the trimming module further comprises an output current module, configured to receive a plurality of currents generated by the PTAT trimming current generator, the CTAT trimming current generator and the reference trimming current generator, and generate a sum current which is the sum of the plurality of received currents to the output signal generating circuit.

10. The electronic device according to claim 7, wherein further comprising:
a heating device, configured to increase the temperature of the electronic device from the first temperature to the second temperature.

11. The electronic device according to claim 7, wherein for the first configuration combinations, the configuration selection module tests whether the output signal oscillates a specific number of times within a specific time, and a length of the specific time is a specific plurality of reference clock periods,
wherein when the output signal oscillates the specific number of times within the specific time, for the first configuration combinations, the configuration selection module determines that the third configuration values of the reference trimming device makes the frequency of the output signal close to the target frequency value based on the first configuration combination, and
wherein when the output signal does not oscillate the specific number of times within the specific time, for the first configuration combinations, the configuration selection module determines that the third configuration values of the reference trimming device does not make the frequency of the output signal close to the target frequency value based on the first configuration combination, then the configuration selection module adjusts the third configuration values of the reference trimming device, and repeats testing until the configuration values of the reference trimming device makes the frequency of the output signal close to the target frequency value.

12. The electronic device according to claim 7, wherein the output signal generating circuit is an oscillator circuit, and the oscillator circuit comprises:
a first current generator, electrically connected to the trimming module, and controlled by the trimming module to provide a first charging current at a current output end of the first current generator;
a first switch, wherein one end of the first switch is electrically connected to a low voltage, and the first switch is controlled by a first oscillation control signal;
a first capacitor, wherein one end of the first capacitor is electrically connected to the current output end of the first current generator and the other end of the first switch, the other end of the first capacitor is electrically connected to the low voltage,
wherein when the first switch is open, the first capacitor receives the first charging current to charge, and
wherein when the first switch is turned on, the first capacitor is configured to discharge;
a second current generator, electrically connected to the trimming module, and controlled by the trimming module to provide a second charging current at a current output end of the second current generator;
a second switch, wherein one end of the second switch is electrically connected to the low voltage, and the second switch is controlled by a second oscillation control signal; and
a second capacitor, wherein one end of the second capacitor is electrically connected to the current output end of the second current generator and the other end of the second switch, and the other end of the second capacitor is electrically connected to the low voltage,
wherein when the second switch is open, the second capacitor receives the second charging current to be charged, and
wherein when the second switch is turned on, the second capacitor is configured to discharge.
